(19) United States
(12) Patent Application Publication
(10) Pub. No.: US 2019/0207652 A1
(43) Pub. Date: Jul. 4, 2019

(54) System and Method for Determining Power Status in a Metering Network

(71) Applicant: Honeywell International Inc., Morris Plains, NJ (US)

(72) Inventors: Sean Scoggins, Rolesville, NC (US); Gerald Paprocki, Cary, NC (US); Navaneet Kumar, Cary, NC (US)

(21) Appl. No.: 15/860,038

(22) Filed: Jan. 2, 2018

(51) Int. Cl. H04B 3/54; H04L 12/24; H02J 13/00; G01R 19/155; G01R 19/15

(52) U.S. Cl. CPC H04B 3/546; H04L 41/0686; H02J 13/0062; H04L 41/0677; H04B 2203/5458; H04B 2203/5433; G01R 19/15; H04Q 2209/60; G01R 19/155

(57) ABSTRACT

A system and method are provided for assessing whether a power outage has occurred at a meter location. The method comprises: maintaining, in a memory of a head-end system, information regarding the communication performance of a meter; receiving, by the head-end system, an indication of a power status of the meter; and determining a likelihood that a power outage has occurred at the meter location based on the information regarding the communication performance and the indication of the power status.

### TECHNICAL FIELD

The present invention relates to a metering system and methods, and more particularly, to systems and methods for requesting data from a metering device.

### BACKGROUND

Utility companies assess the power status of individual metering devices when determining the extent of a power outage in a metering distribution network. To assess the power status, the utility evaluates whether the metering device at a particular location is energized or not. Typically, the utility will select metering devices or other devices at key points on the metering distribution network and request their power status. The utility will use the power status information, which may also include information received from various outage-reporting facilities, such as automated voice response systems, customer calls to customer service representatives, and outage notifications from metering systems, supervisory control and data acquisition (SCADA) systems, and other monitoring systems, to isolate faults on the network. The power status information is also used to determine the boundaries of an outage or confirm whether power has been restored after repairs have been made. With the proliferation of unreliable, low bandwidth networking, the decreasing per-packet reliability of the distribution network results in reduced accuracy in the evaluation of a power outage based on responses to a power status check from the metering device. Thus, a system for increasing the accuracy of a likelihood of a power outage at a particular meter location is desired.

The foregoing background discussion is intended solely to aid the reader. It is not intended to limit the innovations described herein. Thus, the foregoing discussion should not be taken to indicate that any particular element of a prior system is unsuitable for use with the innovations described herein, nor is it intended to indicate that any element is essential in implementing the innovations described herein. The implementations and application of the innovations described herein are defined by the appended claims.

### SUMMARY

The power status check (PSC) functionality offered by current metering distribution networks is intended to provide the power status (e.g. “on” or “off') for devices, such as electricity meters, under management of the distribution network to an Outage Management System (OMS). Since an electricity meter is powered by the distribution network, in an outage, each electricity meter cannot communicate with the utility. This causes most utilities to infer the power status of the particular metering device by doing a communication status check. The assumption is that if a request is sent to a metering device and no response is received from the device, then the device is powered off, and therefore, an outage is confirmed. Likewise, if a response from the device is received, then the device is powered on, and therefore, restoration of power can be confirmed.

The assumption of power status based on the communication state of the metering device leads to over reporting of outage conditions when the communication network is unreliable. Most unreliable networks use mechanisms such as retries, alternate paths, and application layer protocols that deal with unreliability to ensure that information eventually is communicated. Power status checks are frequently implemented using a “ping” type communication and often require near instantaneous successful communication because the request is time sensitive. Waiting minutes or hours to assess the power status is undesirable to utilities from both a customer service and network operations perspective. Therefore, the reliability of the PSC response is highly associated with the individual success rate of packets on the communication network.

Disclosed herein is a method and system for improving the accuracy and precision of inferences made by a metering distribution network regarding the power status of a particular metering device connected to the metering distribution network.

An aspect of the present disclosure provides a method for assessing whether a power outage has occurred at a meter location. The method comprises: maintaining, in a memory of a head-end system, information regarding the communication performance of a meter; receiving, by the head-end system, an indication of a power status of the meter; and determining a likelihood that a power outage has occurred at the meter location based on the information regarding the communication performance and the indication of the power status.

Another aspect of the present disclosure provides a metering system configured to assess whether a power outage has occurred at a meter location. The metering system comprises a memory and a processor. The memory is configured to store and maintain information regarding the communication performance of a meter. The processor is configured to receive an indication of a power status of the meter and determine a likelihood that a power outage has occurred at the meter location based on the information regarding the communication performance of the meter and the indication of the power status of the meter.

This summary is provided to introduce a selection of concepts in a simplified form that are further described below in the Description of the Invention section. This Summary is not intended to identify key features or essential features of the claimed subject matter, nor is it intended to be used to limit the scope of the claimed subject matter. Furthermore, the claimed subject matter is not constrained to limitations that solve any or all disadvantages noted in any part of this disclosure.

### BRIEF DESCRIPTION OF THE DRAWINGS

A more detailed understanding may be had from the following description, given by way of example in conjunction with the accompanying drawings, wherein:

FIG. 1 illustrates a metering system in which the systems, methods, and apparatus disclosed herein may be embodied.

FIGS. 2A and 2B illustrate schematics of a meter in the metering system of FIG. 1, according to an aspect of the disclosure.

FIG. 3 illustrates a block diagram of an example computing environment that may be used to implement aspects of the metering system illustrated in FIG. 1, according to an aspect of the disclosure.

FIG. 4 illustrates a flow diagram for assessing a power outage at a meter location, according to an aspect of the disclosure.

### DESCRIPTION OF THE INVENTION

The disclosure relates generally to metering systems and methods for improving the accuracy and precision of inferences made by a head-end system about a power status of a point on a distribution network.

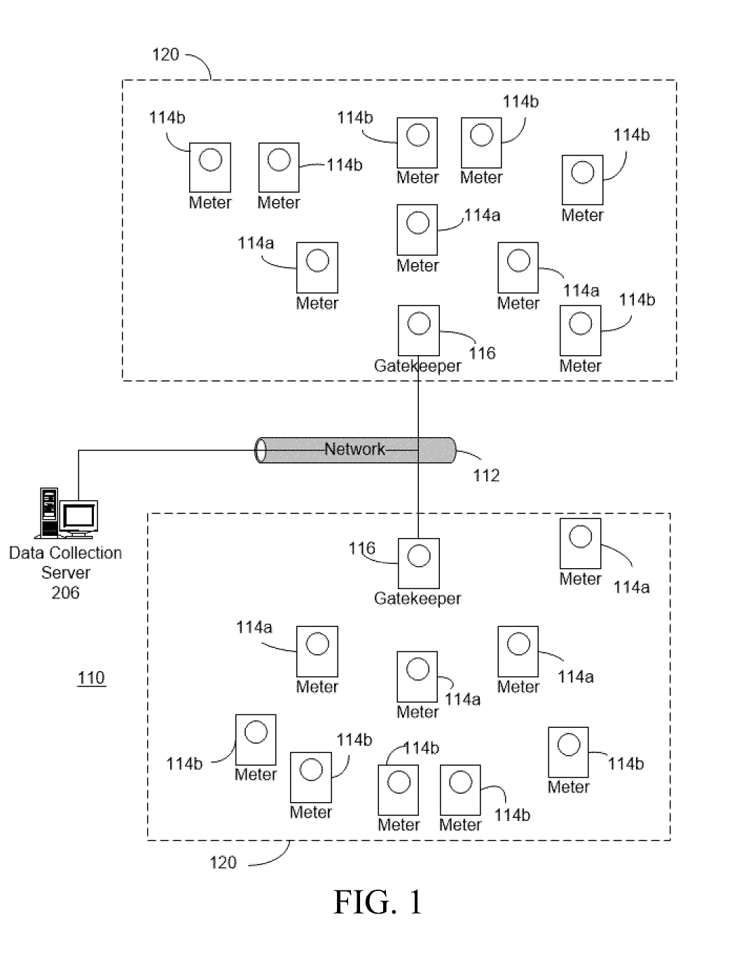

FIG. 1 provides a diagram of an embodiment of a metering system 110 in which the methods, systems, and apparatus disclosed herein may be employed. System 110 comprises a plurality of meters 114, which are operable to sense and record consumption or usage of a service or commodity such as, for example, electricity, water, or gas. Meters 114 may be located at customer premises such as, for example, a home or place of business. Meters 114 comprise circuitry for measuring the consumption of the service or commodity being consumed at their respective locations and for generating data reflecting the consumption, as well as other data related thereto. Meters 114 may also comprise circuitry for wirelessly transmitting data generated by the meter to a remote location. Meters 114 may further comprise circuitry for receiving data, commands or instructions wirelessly as well. Meters that are operable to both receive and transmit data may be referred to as “bi-directional” or “two-way” meters (or nodes), while meters that are only capable of transmitting data may be referred to as “transmit-only” or “one-way” meters. In bi-directional meters, the circuitry for transmitting and receiving may comprise a transceiver.

System 110 further comprises gatekeepers 116. In some embodiments, the gatekeepers 116 may also be referred to as a “collectors” or “routers.” In one embodiment, the gatekeepers 116 are also meters operable to detect and record usage of a service or commodity such as, for example, electricity, water, or gas. In addition, gatekeepers 116 are operable to send data to and receive data from meters 114. Thus, like the meters 114, the gatekeepers 116 may comprise both circuitry for measuring the consumption of a service or commodity and for generating data reflecting the consumption and circuitry for transmitting and receiving data. In one embodiment, gatekeeper 116 and meters 114 communicate with and amongst one another using a frequency hopping communications technique, such as, for example, a frequency hopping spread spectrum (FHSS) technique or direct sequence spread spectrum (DSSS).

In one embodiment, the gatekeepers 116 and the meters 114 with which it communicates define a subnet or local area network (LAN) 120. The LAN 120 may define a controlled, wireless mesh network with the gatekeepers 116 of that LAN effectively controlling the mesh network.

As used herein, the gatekeepers 116 and the meters 114 may be referred to as “nodes” in the subnet/LAN 120. In the subnet/LAN 120, the meters 114 transmit data related to consumption of the commodity being metered at the meter's location. The gatekeepers 116 receive the data transmitted by each meter 114, effectively “collecting” it, and then periodically transmit the data from all of the meters in the subnet/LAN 120 to a data collection server 206 (e.g. utility head-end system). The data collection server 206 stores, updates, and maintains the data for analysis and preparation of bills, for example. The data collection server 206 may be a specially programmed general purpose computing system and may communicate with gatekeepers 116 via a network 112. The network 112 may comprise any form of network, including a wireless network or a fixed-wire network, such as a local area network (LAN), a wide area network (WAN), the Internet, an intranet, a telephone network, such as the public switched telephone network (PSTN), a Frequency Hopping Spread Spectrum (FHSS) radio network, a mesh network, a Wi-Fi (802.11) network, a Wi-Max (802.16) network, a land line (POTS) network, a TCP/IP network, a W-WAN, a GPRS network, a CDMA network, a Fiber network, or any combination of the above.

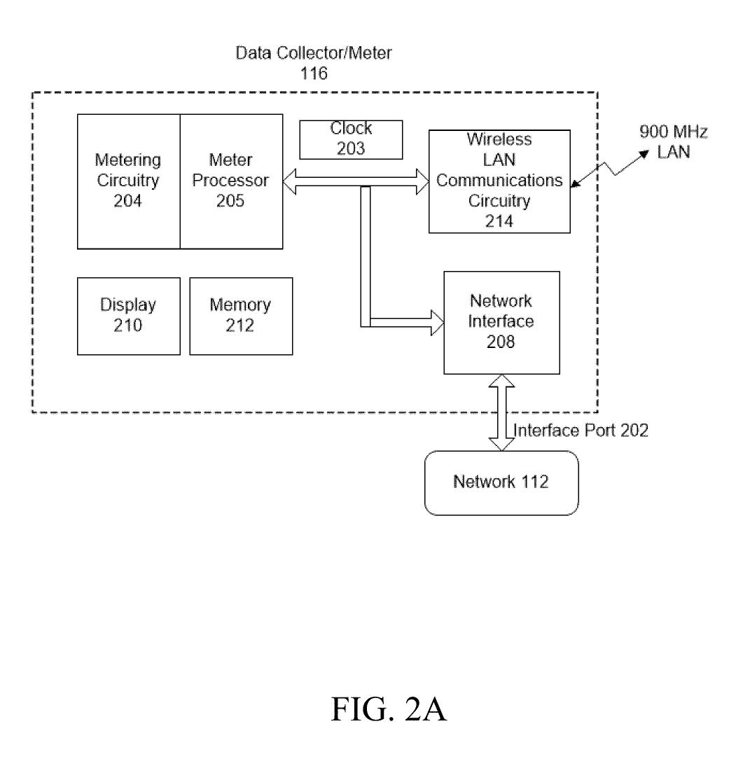

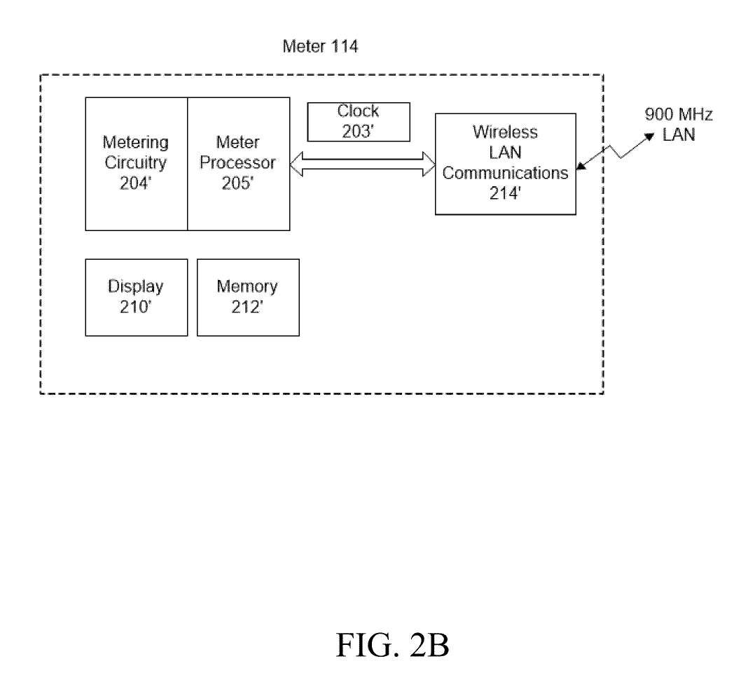

FIG. 2A is a block diagram illustrating further details of one embodiment of a gatekeeper 116. Although certain components are designated and discussed with reference to FIG. 2A, it should be appreciated that the invention is not limited to such components. In fact, various other components typically found in an electronic meter may be a part of gatekeeper 116, but have not been shown in FIG. 2A for the purposes of clarity and brevity. Also, the invention may use other components to accomplish the operation of gatekeeper 116. The components that are shown and the functionality described for gatekeeper 116 are provided as examples, and are not meant to be exclusive of other components or other functionality.

As shown in FIG. 2A, gatekeeper 116 may comprise metering circuitry 204 that performs measurement of consumption of a service or commodity and a processor 205 that controls the overall operation of the metering functions of the gatekeeper 116. The gatekeeper 116 may further comprise a display 210 for displaying information such as measured quantities and meter status and a memory 212 for storing data. The gatekeeper 116 further comprises wireless LAN communications circuitry 214 for communicating wirelessly with the meters 114 in a subnet/LAN and a network interface 208 for communication over the network 112. The communications circuitry 214 may be a two-way communications interface to the data collection server 206 and may comprise any suitable communications interface technology, such as a radio frequency (RF) transceiver, or an interface to the telephone lines or power lines at a utility location, etc. The communications circuitry 214 may communicate with the data collection server 206 over private or public networks.

As further shown, the gatekeeper 116 includes a clock circuit 203. The clock circuit 203 for the gatekeeper 116 may run off an internal 12 MHz crystal and may be adjusted from the central station on a daily basis (or more often). During outages, the clock circuit 203 may keep using a 32 kHz crystal. In an alternative embodiment, the gatekeeper 116 may use a 60 Hz line frequency for additional timing accuracy adjustments.

FIG. 2B is a block diagram of an exemplary embodiment of a meter 114 that may operate in the system 110 of FIG. 1. As shown, the meter 114 comprises metering circuitry 204′ for measuring the amount of a service or commodity that is consumed, a processor 205′ that controls the overall functions of the meter, a display 210′ for displaying meter data and status information, and a memory 212′ for storing data and program instructions. The meter 114 further comprises wireless communications circuitry 214′ for transmitting and receiving data, such as error and warning conditions, to/from other meters 114 or the gatekeeper 116. The wireless communications circuitry 214′ may be similar to or identical to the wireless communication circuitry 214 in the gatekeeper 116 of FIG. 2A. The meter 114 also comprises a clock circuit 203′ like the gatekeeper 116. The clock circuit 203′ may be similar or identical to the clock circuit 203 used in the gatekeeper 116.

The gatekeepers 116 may be responsible for managing, processing and routing data communicated between the gatekeeper 116 and network 112 and between the gatekeeper 116 and meters 114. The gatekeepers 116 may continually or intermittently receive current data from meters 114 and store the data in memory 212 or a database (not shown) in gatekeeper 116. Such current data may include but is not limited to the total kWh usage, the Time-Of-Use (TOU) kWh usage, peak kW demand, other energy consumption measurements, error and warning conditions, or other status information. The gatekeepers 116 also may receive and store previous billing and previous season data from meters 114 and store the data in memory 212 or the database in gatekeeper 116. The database may be implemented as one or more tables of data within the gatekeeper 116.

In an embodiment, the metering system 110 may be an Advanced Metering Infrastructure (AMI) system which uses the ANSI C12.22 protocol for interfacing with the network 112. It should be appreciated that other protocols may be used for the methods and systems for data communications defined herein, for example, ANSI C12.18 and ANSI C12.21. The protocol makes provisions for encrypting data to enable secure communications, including confidentiality and data integrity, for the purpose of interoperability between metering devices and the network.

In an embodiment, the LAN/subnet 120 formed by the gatekeepers 116 and the plurality of meters 114 that communicate with it may operate to form a wireless mesh network that implements FHSS techniques in the 900 MHz ISM band. It should be appreciated that the system and method disclosed herein may comply with Federal Communications Commission (FCC) part 15.247 while providing mechanisms for devices (e.g., meters 114 and gatekeepers 116) to join, register, synchronize, and find neighbors within a LAN/subnet.

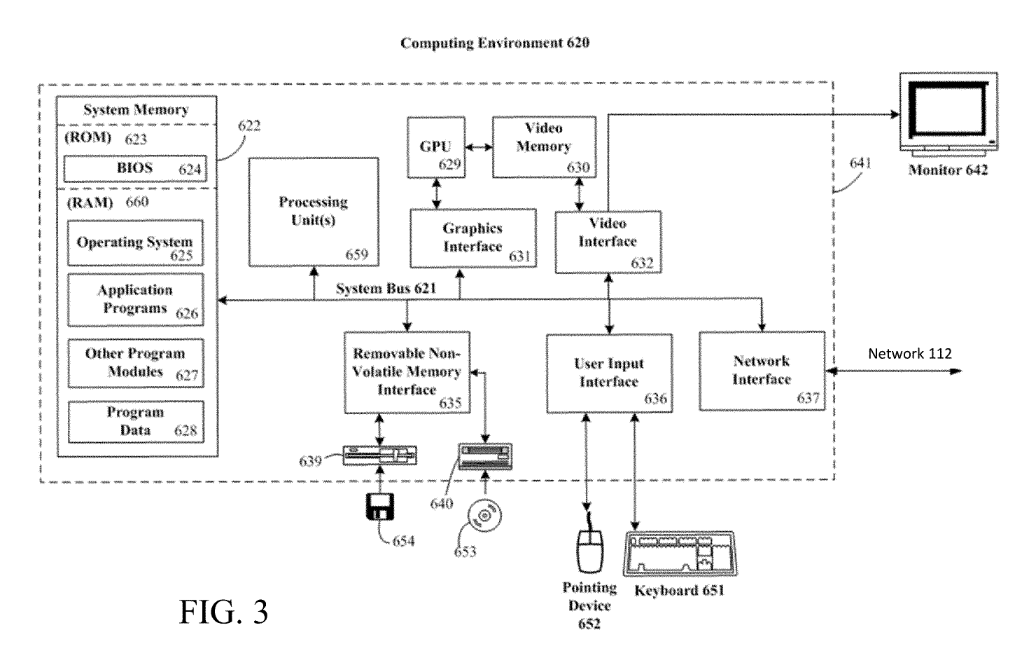

FIG. 3 is an example embodiment of a computing environment 620 of which various aspects of the metering system 110 could be implemented. For example, the computing environment 620 may be used to implement the data collection server 206, or any other aspect of the disclosed system that requires computing. The computing environment 620 is only one example of a suitable computing environment and is not intended to suggest any limitation as to the scope of use or functionality of the presently disclosed subject matter. Neither should the computing environment 620 be interpreted as having any dependency or requirement relating to any one or combination of components illustrated in FIG. 3. In some embodiments, the various depicted computing elements may include circuitry configured to instantiate specific aspects of the present disclosure. For example, the term circuitry used in the disclosure can include specialized hardware components configured to perform function(s) by firmware or switches. In other example embodiments, the term circuitry can include a general purpose processing unit, memory, etc., configured by software instructions that embody logic operable to perform function(s). In example embodiments where circuitry includes a combination of hardware and software, an implementer may write source code embodying logic and the source code can be compiled into machine readable code that can be processed by the general purpose processing unit. Since the state of the art has evolved to a point where there is little difference between hardware, software, or a combination of hardware/software, the selection of hardware versus software to effectuate specific functions is a design choice left to an implementer. More specifically, a software process can be transformed into an equivalent hardware structure, and a hardware structure can itself be transformed into an equivalent software process. Thus, the selection of a hardware implementation versus a software implementation is one of design choice and left to the implementer.

In FIG. 3, the computing environment 620 comprises a computer 641. The computer 641 comprises a processing unit(s) 659, which may comprise a general purpose processor, a special purpose processor, a conventional processor, a digital signal processor (DSP), a plurality of microprocessors, one or more microprocessors in association with a DSP core, a controller, a microcontroller, Application Specific Integrated Circuits (ASICs), Field Programmable Gate Array (FPGAs) circuits, any other type of integrated circuit (IC), a state machine, and the like. The processing unit(s) 659 may perform signal coding, data processing, power control, input/output processing, and/or any other functionality that enables the computing environment 620 to operate in accordance with its intended functionality. The computer 641 may further comprise a graphics interface, graphics processing unit (GPU), video memory 630, and video interface. These components may cooperate to display graphics and text on a video monitor, such as monitor 642. Processing unit(s) 659 and GPU 629 may receive, generate, and process data related to the methods and apparatuses disclosed herein.

In operation, processing unit(s) 659 fetches, decodes, and executes instructions, and transfers information to and from other resources via the computer's main data-transfer path, system bus 621. Such a system bus connects the components in computer 641 and defines the medium for data exchange. System bus 621 typically includes data lines for sending data, address lines for sending addresses, and control lines for sending interrupts and for operating the system bus. An example of such a system bus 621 is the PCI (Peripheral Component Interconnect) bus. A system memory 622 includes computer storage media in the form of volatile and/or nonvolatile memory such as read only memory (ROM) 623 and RAM 660. A basic input/output system 624 (BIOS), containing the basic routines that help to transfer information between elements within computer 641, such as during start-up, is typically stored in ROM 623. RAM 660 typically contains data, data tables, and/or program modules that are immediately accessible to and/or presently being operated on by processing unit 659. By way of example, and not limitation, FIG. 3 illustrates operating system 625, application programs 626, other program modules 627, and program data 628.

The computer 641 may also include other removable/non-removable, volatile/nonvolatile computer storage media. By way of example only, the computer 641 may include a hard disk drive (not shown) that reads from or writes to non-removable, nonvolatile magnetic media, a magnetic disk drive 639 that reads from or writes to a removable, nonvolatile magnetic disk 654, and an optical disk drive 640 that reads from or writes to a removable, nonvolatile optical disk 653 such as a CD ROM or other optical media. Other removable/non-removable, volatile/nonvolatile computer storage media that can be used in the exemplary operating environment include, but are not limited to, magnetic tape cassettes, flash memory cards, digital versatile disks, digital video tape, solid state RAM, solid state ROM, and the like. Magnetic disk drive 639 and optical disk drive 640 are typically connected to the system bus 621 by a removable memory interface, such as interface 635. The drives and their associated computer storage media discussed above and illustrated in FIG. 3, provide storage of computer readable instructions, data structures, program modules and other data for the computer 641.

A user may enter commands and information into the computer 641 through input devices such as a keyboard 651 and pointing device 652, commonly referred to as a mouse, trackball or touch pad. Other input devices (not shown) may include a microphone, joystick, game pad, satellite dish, scanner, or the like. These and other input devices are often connected to the processing unit 659 through a user input interface 636 that is coupled to the system bus, but may be connected by other interface and bus structures, such as a parallel port, game port or a universal serial bus (USB). The computer may connect to a local area network or wide area network, such as network 112, through a network interface or adapter 637.

Thus, it is understood that any or all of the apparatuses, systems, methods and processes described herein may be embodied in the form of computer executable instructions (i.e., program code) stored on a computer-readable storage medium which instructions, when executed by a processor, such as processing unit(s) 659, cause the processor to perform and/or implement the systems, methods and processes described herein. Specifically, any of the steps, operations or functions described herein may be implemented in the form of such computer executable instructions, executing on the processor of a computing system or other computing apparatus. Computer readable storage media include both volatile and nonvolatile, removable and non-removable media implemented in any non-transitory (i.e., tangible or physical) method or technology for storage of information, but such computer readable storage media do not includes signals. Computer readable storage media include, but are not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other tangible or physical medium which can be used to store the desired information and which can be accessed by a computing system.

The system memory 622 of the computing environment 620 may be configured to maintain information regarding the communication performance of each meter 114 and gatekeeper 116. For example, the system memory 622 may maintain statistics about the communication success rate between the data collection server 206 and each meter 114 and gatekeeper 116. The stored information may be continuously and automatically maintained in the system memory 622. The stored information may be used to predict the success rate of communications in the future.

The information stored and maintained in the system memory 622 regarding communications between the data collection server 206 and each meter 114 or gatekeeper 116 may include, for example, how many communication attempts and failures were made, the time it took to send and receive communications (i.e. total roundtrip time), the time of day the communications were sent, the season the communications were sent (i.e. for foliage effects), and the time between frequency hops. Based on the information regarding the communication performance, the data collection server 206 may calculate a value that indicates a predictive expectation of communication success of the particular meter 114 or gatekeeper 116. Additionally, the data collection server 206 may calculate a value that indicates a predicted response time to a data collection server 206 request, and a value that indicates the likelihood of receiving a response at the time the data collection server 206 request is made. Each of these calculated values may be stored in the system memory 622.

The information stored and maintained in the system memory 622 may be used to determine a likelihood that a power outage has occurred at a meter location. For example, during a power status check, the data collection server 206 may send a power status request to the meter 114. The response, or lack of response, from the meter 114 may be used along with the information regarding the communication performance to determine a likelihood that a power outage has occurred.

Using the value indicative of predicted response time, the data collection server 206 may reduce the amount of time waiting for a response to a meter request. This is beneficial because a significant amount of time may be spent by the data collection server 206 waiting for a response from the meter 114. Each meter 114 or gatekeeper 116 may have significant differences in response times to a meter request. Therefore, storing and maintaining meter response times may enable the data collection server 206 to predict future response times. As an example, using a multi-hop RF mesh network, response times from a level 1 meter 114 may be approximately 1 second. Whereas a level 8 meter 114 may respond in approximately 8 seconds. Similarly, a meter 114 in a particularly challenging RF environment may require so many retries that it may require twice as long to respond to a request as a nearby meter 114. By using the meter response information, a system power status request can time out faster and the overall power status check process can be performed quicker.

Using the value that indicates a predictive expectation of communication success of the particular meter 114 or gatekeeper 116 in response to a request, the data collection server 206 may determine a likelihood of receiving a response as input for determining the likelihood of a power outage (e.g. making an inference whether a power outage has occurred at the meter location). For example, an average communication success rate may be calculated using the information regarding whether a response has been received by the data collection server 206 stored in the system memory 622 over the past 30 days (i.e. a 90% success rate). A 90% success rate would indicate there is a strong likelihood of a power outage at the meter 114 location if a response to a power status check has not been received by the data collection server 206 from the meter 114. Conversely, a 30% calculated communication success rate would indicate a weaker likelihood of a power outage at the meter 114 location if a response to a power status check has not been received by the data collection server 206 from the meter 114. The predicted communication success rate may therefore provide a confidence level in determining a likelihood that a power outage has occurred at a meter 114 location.

The following examples illustrate how the data collection server 206 may determine the likelihood of a power outage at the meter 114.

In a first example, the following information regarding meter 114 may be received and stored in the system memory 622:

Percent success of request/response communication to the device over 7 days: 85%

95 ^{th} percentile latency between request and response to the device over 7 days: 2,400 ms

Percent success of request/response communication to the device over 30 days: 89%

95^{th} percentile latency between request and response to the device over 30 days: 1,800 ms

Number of ping requests sent to the device for power status check: 10

Number of responses received from the device for power status check: 0

The automatically selected timeout value used for ping requests: 3,000 ms

Amount of time passes since system has heard from the device: 14,300 sec

The last known power state based on communication from the device: power restored

The inferred power state (e.g. response to the power status check): power outage

Based on the information received and stored in the system memory 622, the data collection server 206 may determine that the meter 114 has a high likelihood of having a power outage (e.g. 90% likelihood). The factors in this example that lead to the high likelihood of a power outage are: 1.) the historically high success rate (e.g. 85% and 89%) coupled with the number of responses received from the device for the power status check (e.g. 0), 2.) the data collection server 206 has not received a message from the device indicating that the power is out (e.g. last known power state is ‘power restored’), and 3.) the data collection server 206 has received a message within the past 24 hours (e.g. 14,300 sec have passed since previous communication).

In a second example, the following information regarding meter 114 may be received and stored in the system memory 622:

Percent success of request/response communication to the device over 7 days: 75%

95^{th} percentile latency between request and response to the device over 7 days: 2,000 ms

Percent success of request/response communication to the device over 30 days: 75%

95^{th} percentile latency between request and response to the device over 30 days: 2,000 ms

Number of ping requests sent to the device for power status check: 10

Number of responses received from the device for power status check: 0

The automatically selected timeout value used for ping requests: 3,000 ms

Amount of time passes since system has heard from the device: 14,400 sec

The last known power state based on communication from the device: power outage

The inferred power state (e.g. response to the power status check): power outage

Based on the information received and stored in the system memory 622, the data collection server 206 may determine that the meter 114 has a very high likelihood of having a power outage (e.g. 99% likelihood). The factors in this example that lead to the very high likelihood of a power outage are: the historically consistent success rate (e.g. 75% over 7 days and 75% over 30 days) coupled with the number of responses received from the device for the power status check (e.g. 0), 2.) the system received a positive outage indication from the device, and 3.) the data collection server 206 has received a message within the past 24 hours (e.g. 14,400 sec have passed since previous communication).

In a third example, the following information regarding meter 114 may be received and stored in the system memory 622:

Percent success of request/response communication to the device over 7 days: 25%

95^{th} percentile latency between request and response to the device over 7 days: 8,000 ms

Percent success of request/response communication to the device over 30 days: 30%

95^{th} percentile latency between request and response to the device over 30 days: 8,000 ms

Number of ping requests sent to the device for power status check: 10

Number of responses received from the device for power status check: 0

The automatically selected timeout value used for ping requests: 8,000 ms

Amount of time passes since system has heard from the device: 57,900 sec

The last known power state based on communication from the device: power restored

The inferred power state (e.g. response to the power status check): power outage

Based on the information received and stored in the system memory 622, the data collection server 206 may determine that the meter 114 has a low likelihood of having a power outage (e.g. 25% likelihood). The factors in this example that lead to the low likelihood of a power outage are: the historically low success rate (e.g. 25% over 7 days and 30% over 30 days) coupled with the number of responses received from the device for the power status check (e.g. 0), 2.) the system received a positive outage indication from the device (e.g. last known power state is ‘power restored’), and 3.) the data collection server 206 has not received a message within the past 24 hours (e.g. 57,900 sec have passed since previous communication).

For each value received and stored in the system memory 622 of the meter 114, a scale factor and a weight factor may be associated with the value. The scale factor and the weight factor may be used to determine the likelihood that a power outage has occurred. The scale factor provides an estimate regarding how each individual piece of information received is scaled relative to that type of information. For example, with respect to the historical success rate, a high success rate (e.g. 75%) may result in a high scale factor (e.g. 90%-100%). The weight factor weighs each piece of information relative to other types of information. For example, the historical success rate may be given a high weight factor (e.g. 50%) due to the importance of that piece of information in calculating the likelihood of a power outage.

In an aspect, each scale factor is unique based on each type of information, and each weight factor has an equal weight. For example, in the first above example described above, the historical success rate, the last known power state, the responses to the power status check, and the length of time since last communication with device may all be associated with a weight factor of 25%. The scale factors may all be unique and range from “0” to “1,” with “0” indicating a low confidence in determining the power status, and with “1” indicating a high confidence in the determining of the power status. Based on the values in the first example, the scale factor for the historical success rate may be associated with a value of 0.9, the scale factor for the last known power state may be associated with a value of 1.0, the scale factor for the responses to the power status check may be associated with a value of 1.0, and the scale factor for the length of time since the last communication may be associated with a value of 0.9. Based on the weight factors and scale factors in this example, the likelihood of a power outage is 90%.

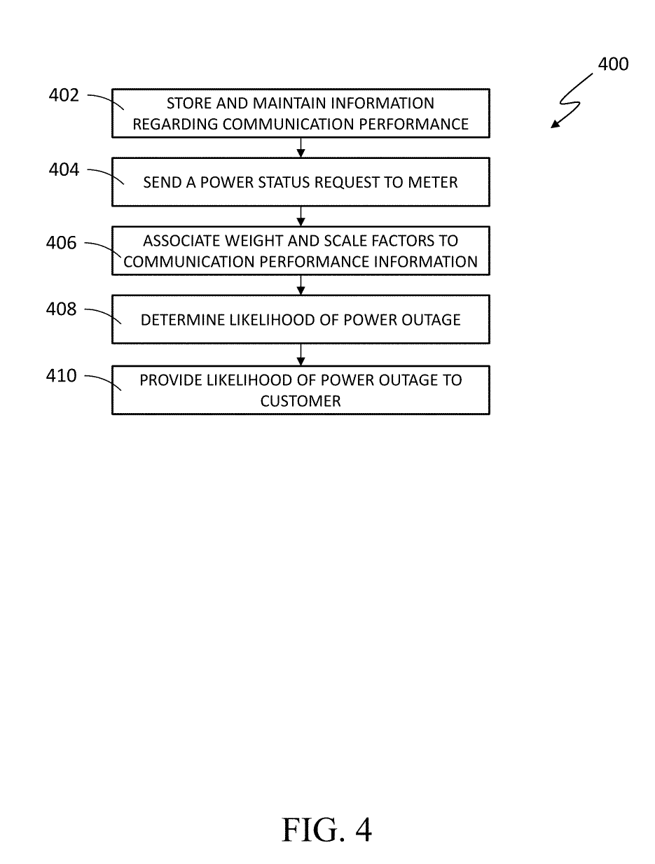

FIG. 4 illustrates a method 400 for assessing whether a power outage has occurred at a meter 114 location, according to an aspect of this disclosure. Method 400 may be performed on one or more meters 114 and/or one or more gatekeepers 116. At step 402, information regarding the communication performance of the meter 114 is stored and maintained in the system memory 622. The communication performance information includes, for example, the predicted communication success rate, the predicted response time to a request from the head-end system 206, most recent power status of the meter 114 during a power status check, current outage state or last known power state of the meter 114, and a response or lack of response by the meter 114 to the head-end system 206 based on a meter ping. The predicted communication success rate may be based on, for example, a number of attempts and failures to communicate with the meter, a time it takes to send and receive information to and from the meter, a time of day, a time of season, and a time between frequency hops.

At step 404, the head-end system 206 may send a power status request (e.g. ping) to the meter 114. This meter ping may be sent to a single meter 114, or may be broadcasted to a plurality of meters 114 and/or gatekeepers 116. The meter 114 receives the ping and may either send a response or may fail to send a response to the head-end system 206. The response, or response failure, may indicate the power status of the meter 114, which is then stored and maintained in the system memory 622.

At step 406, each value of the communication performance information stored in the memory 622 is associated with a scale factor and a weight factor. The scale factors and weight factors may be updated or modified based on the importance of each value of the communication performance information. At step 408, the processing unit 659 may determine a likelihood that a power outage has occurred at the meter location based on the information regarding the communication performance and the indication of the power status of the meter 114. The likelihood that a power outage has occurred may include determining a probability value for a probability that a power outage has occurred at the meter location based on the scale factors and weight factors. At step 410, the likelihood that a power outage has occurred may be provided to the customer.

While the disclosure is described herein using a limited number of embodiments, these specific embodiments are for illustrative purposes and are not intended to limit the scope of the disclosure as otherwise described and claimed herein. Modification and variations from the described embodiments exist. The scope of the invention is defined by the appended claims.

1. A method for assessing whether a power outage has occurred at a meter location, the method comprising:
maintaining, in a memory of a head-end system comprising a data collection server, information regarding communication performance of a meter;
receiving, by the head-end system, an indication of a power status of the meter;
and determining a likelihood that a power outage has occurred at the meter location based on the information regarding the communication performance and the indication of the power status.

2. The method recited in claim 1, wherein the information regarding the communication performance comprises a predicted communication success rate between the meter and the head-end system during a power status check.

3. The method recited in claim 2, wherein the predicted communication success rate is based on at least one of the following: i.) attempts and failures to communicate with the meter, ii.) time it takes to send and receive information to and from the meter, iii.) time of day information, iv.) time of season information, and v.) time between frequency hops.

4. The method recited in claim 1, wherein the information regarding the communication performance comprises a predicted response time to a request from the head-end system to the meter.

5. The method recited in claim 1, wherein the information regarding the communication performance comprises a most recent power status of the meter during a power status check.

6. The method recited in claim 1, wherein the information regarding the communication performance comprises a current outage state of the meter.

7. The method recited in claim 1, wherein the indication of the power status of the meter comprises a response or lack of response by the meter to the head-end system based on a meter ping.

8. The method recited in claim 1, wherein determining the likelihood that a power outage has occurred at the meter location comprises determining a probability value based on a probability that a power outage has occurred at the meter location.

9. The method recited in claim 1, further comprising:
pinging the meter by the head-end system;
receiving, by the head-end system, a response from the meter; and
determining a likelihood that a power outage has occurred at the meter location based on the response from the meter.

10. A metering system configured to assess whether a power outage has occurred at a meter location, the metering system comprising:
a memory configured to store and maintain information regarding 4-4e communication performance of a meter; and
a processor configured to:
receive an indication of a power status of the meter, and
determine a likelihood that a power outage has occurred at the meter location based on the information regarding communication performance of the meter and the indication of the power status of the meter;
wherein the information regarding the-communication performance of the meter comprises a predicted communication success rate between the meter and a head-end system during a power status check wherein the head-end system comprises a data collection server.

11. The metering system of claim 10, further comprising:
a transceiver configured to receive the indication of the power status of the meter.

12. The metering system recited in claim 11, wherein the transceiver is further configured to: ping the meter;
receive a response from the meter; and
determine a likelihood that a power outage has occurred at the meter location based on the response from the meter.

13. (canceled)

14. The metering system recited in claim 10, wherein the predicted communication success rate is based on at least one of the following: i.) attempts and failures to communicate with the meter, ii.) time it takes to send and receive information to and from the meter, iii.) time of day information, iv.) time of season information, and v.) time between frequency hops.

15. The metering system recited in claim 10, wherein the information regarding communication performance of the meter comprises a predicted response time to a request sent to the meter.

16. The metering system recited in claim 10, wherein the information regarding communication performance of the meter comprises a most recent power status of the meter during a power status check.

17. The metering system recited in claim 10, wherein the information regarding communication performance of the meter comprises a current outage state of the meter.

18. The metering system recited in claim 10, wherein the indication of the power status of the meter comprises a response or lack of response by the meter based to a meter ping.

19. The metering system recited in claim 10, wherein the processor is further configured to determine a probability value based on a probability that a power outage has occurred at the meter location.

20. The system recited in claim 10, wherein the meters are located on one or more premises, the head-end system is a utility head-end system, the meters forms a network with one or more gatekeepers, and the head-end system communicates with the meters via the network.
